(19) United States
(12) Patent Application Publication
(10) Pub. No.: US 2008/0018350 A1
(43) Pub. Date: Jan. 24, 2008

(54) Test probe for integrated circuits with ultra-fine pitch terminals

(76) Inventors: Clinton Chao, Hsinchu (TW); Chih-Hsien Chang, Taipei (TW); John C.Y. Chiang, Hsin-Chu (TW); Mark Shane Peng, Hsinchu City (TW); Hua-Shu Wu, Hsinchu (TW); Kim Chen, Fremont, CA (US); Wen-Hung Wu, Hsinchu City (TW); Tjandra Winada Karta, Hsinchu (TW)

Correspondence Address: SLATER & MATSIL, L.L.P., 17950 PRESTON ROAD, SUITE 1000, DALLAS, TX, 75252, US

(21) Appl. No.: 11/525,581

(22) Filed: Sep. 22, 2006

Related U.S. Application Data
(60) Provisional application No. 60/832,639, filed on Jul. 21, 2006.

(51) Int. Cl. G01R 31/02

(52) U.S. Cl. 324/754

(57) ABSTRACT

An interposer for converting pitches includes an interconnect structure over the semiconductor substrate, an active circuit formed on the semiconductor substrate, wherein the active circuit is electrically connected to the interconnect structure, a first plurality of pads with a first pitch over the interconnect structure, a second plurality of pads underlying the semiconductor substrate, and a plurality of through-substrate vias in the semiconductor substrate, wherein the first and the second plurality of pads are interconnected through the plurality of through-substrate vias.

This application claims the benefit of U.S. Provisional Application No. 60/832,639, filed Jul. 21, 2006, entitled “Test Probe for Integrated Circuits with Ultra-Fine Pitch Terminals,” which application is hereby incorporated herein by reference.

### TECHNICAL FIELD

This invention relates generally to integrated circuits, and more particularly to the testing of integrated circuits.

### BACKGROUND

Chip probing is a wafer level technology for determining the quality of semiconductor chips on wafers. The chips are tested before they are sawed from wafers, and only those chips that pass the probe tests are packaged. By identifying problematic chips at an early stage, packaging costs are saved.

FIG. 1 schematically illustrates a simplified, automated chip-probing system, which includes a wafer-probing station 2 and connecting wires 4. Wafer-probing station 2 is used for making electrical contacts to bonding pads on wafers. Wafer-probing station 2 typically contains a load board or probe head 6. Wafer-probing station 2 is connected to automated test equipment (ATE) 8, which includes circuits for testing the chips.

The automated test system is typically very expensive. It is therefore designed as a general-purpose tool for testing different integrated circuits with different designs. The flexibility of use is derived by storing a number of testing programs in ATE 8, and the appropriate testing program may be selected by a user interface prior to each test. In addition, different integrated circuits may have a different input/output (I/O), power, and ground pin layouts. Therefore, the chip-probing system must be able to account for these differences. Commonly, this flexibility is achieved by using probe cards.

A probe card is an interface card between probe head 6 and the semiconductor chip. The probe card translates the fixed pin-out capabilities, such as hard-wired input channels or output channels, of ATE 8 into a flexible arrangement of pins customized for a specific IC design. In this way, ATE system 8 can be used to test a number of different designs using a common, and often quite expensive, probe head 6. A probe card typically includes a plurality of probe pins arranged in a certain style. Through probe head 6, the probe pins are electrically connected to ATE 8.

FIG. 2 schematically illustrates a contact scheme between a probe card 10 and a semiconductor chip 14. Probe card 10 is attached to probe head 6 to provide electrical coupling to ATE 8 and to allow alignment and vertical movement. In a typical arrangement, probe card 10 is aligned to a first semiconductor chip on a wafer. Electrical connection is then engaged by vertically moving probe card 10 down until probe pins 12 come into contact with contact pads 16. After successful alignment and testing of the first semiconductor chip, probe card 10 may be indexed across the wafer to test other semiconductor chips.

Cobra probe cards, membrane probe cards, and cantilever probe cards are among the most commonly used probe cards. Cobra probe cards have the advantageous feature of having array-type pins. Membrane probe cards, with membrane contacts to semiconductor chips, have the advantageous feature of having controlled impedances. Cobra and membrane probe cards, however, typically have large pitches. The minimum pitches of their probe pins are about 160 μm and about 180 μm, respectively. Therefore, they are not suitable for testing wafers with very fine pitches. Particularly, with the scaling of integrated circuits, the pitches of the contact pads on wafers will continue to reduce, posing greater problems for chip probing.

Cantilever probe cards, on the other hand, have finer pitches. Their minimum pitch can be as small as about 45 μm. However, the contact pins on cantilever probe cards are limited to the peripherals of the probe cards. As such, cantilever probe cards cannot be used for probing chips with array-type contact pads.

Therefore, a solution for probing chips having increasingly smaller pitches and/or different designs is needed.

### SUMMARY OF THE INVENTION

In accordance with one aspect of the present invention, an apparatus for testing integrated circuits includes a substrate, an interconnect structure over the substrate, a first plurality of pads with a first pitch over the interconnect structure, wherein the first pitch is configured to match a pitch of a chip-probing system, a second plurality of pads underlying the substrate, wherein the second plurality of pads have a second pitch matching a pitch of bonding pads on semiconductor chips, and wherein the second pitch is smaller than the first pitch, and a plurality of through-substrate vias in the semiconductor substrate, wherein the first and the second plurality of pads are interconnected through the plurality of through-substrate vias,

In accordance with another aspect of the present invention, an interposer for converting pitches includes an interconnect structure over the semiconductor substrate, an active circuit formed on the semiconductor substrate, wherein the active circuit is electrically connected to the interconnect structure, a first plurality of pads with a first pitch over the interconnect structure, a second plurality of pads underlying the semiconductor substrate, and a plurality of through-substrate vias in the semiconductor substrate, wherein the first and the second plurality of pads are interconnected through the plurality of through-substrate vias.

In accordance with yet another aspect of the present invention, a chip-probing system includes a probe head comprising probe pins/pads and an interposer. The interposer includes a substrate, a first plurality of contact pads on a first side of the interposer and electrically connected to the probe pins/pads, wherein the first plurality of contact pads have a first pitch, a second plurality of contact pads on a second side of the interposer opposite the first side, wherein the second plurality of contact pads have a second pitch less than the first pitch, and through-substrate vias in the substrate and interconnecting the first and the second plurality of contact pads.

In accordance with yet another aspect of the present invention, a method of probing a semiconductor chip includes providing a semiconductor chip having a plurality of bonding pads thereon, providing probing equipment, and connecting an interposer between the semiconductor chip and the probing equipment. The interposer comprises a first plurality of contact pads on a first side of the interposer and in physical contact with the probing equipment, and a second plurality of contact pads on a second side of the interposer and connected to the bonding pads, wherein the first and the second plurality of contact pads are interconnected by through-substrate in a substrate of the interposer.

The interposer acts as a pitch converter, converting fine pitches on semiconductor chips to greater pitches of the chip-probing system. The existing chip-probing system thus can continue to be used.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 schematically illustrates a conventional chip-probing system;

FIG. 2 schematically illustrates a conventional contact scheme between a chip-probing system and a semiconductor chip;

FIGS. 3 through 6C are cross-sectional views of intermediate stages in the manufacture of a preferred interposer embodiment;

FIGS. 7A and 7B illustrate connection schemes between a chip-probing system and a semiconductor chip, wherein an interposer is connected between the chip-probing system and the semiconductor chip;

FIG. 8 illustrates an interposer with metal lines for modifying impedances;

FIG. 9 illustrates an interposer comprising built-in active circuits; and

FIG. 10 illustrates an interposer wherein contact pads on the substrate have greater pitches than the pitches of contact pads on interconnect structures.

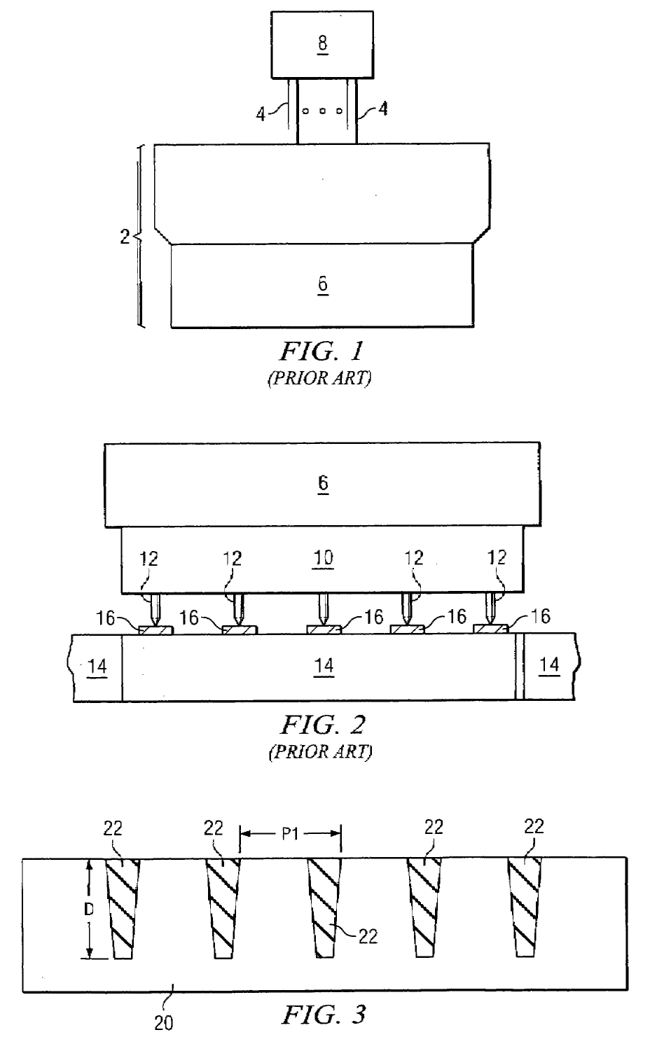

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

A novel method of probing semiconductor chips, which uses an interposer to convert fine pitches on the semiconductor chips to the pitches of a chip-probing system, is discussed. The intermediate stages of manufacturing an interposer are illustrated. Throughout the various views and illustrative embodiments of the present invention, like reference numbers are used to designate like elements. By converting the pitches, the existing chip-probing systems, which have greater pitches than the pitches of existing and/or future small-scale integrated circuits, can continue to be used.

FIGS. 3 through 6C illustrate an exemplary embodiment for forming an interposer. Referring to FIG. 3, a substrate 20 is provided. In the preferred embodiment, substrate 20 comprises commonly used semiconductor materials for forming semiconductor devices thereon, which include silicon, germanium, and combinations thereof. In other embodiments, substrate 20 may have a semiconductor-on-insulator structure.

Deep plugs 22 are formed in substrate 20. The formation processes of deep plugs 22 preferably include plasma etching to form openings during which process a mask layer, such as a photo resist, is formed and patterned. The openings are then filled with materials having different etching characteristics from substrate 20, preferably dielectric materials, resulting in deep plugs 22. Alternatively, the openings may be formed by laser drilling. Deep plugs 22 preferably have a depth D greater than about 5 μm to about 100 μm. The pitches P1 between deep plugs 22 are preferably less than about 60 μm. In practical cases, the pitches P1 match the pitches of the bonding pads on the semiconductor chips to be tested. Therefore, the pitches P1 may be of any value, and may even be less than about 20 μm.

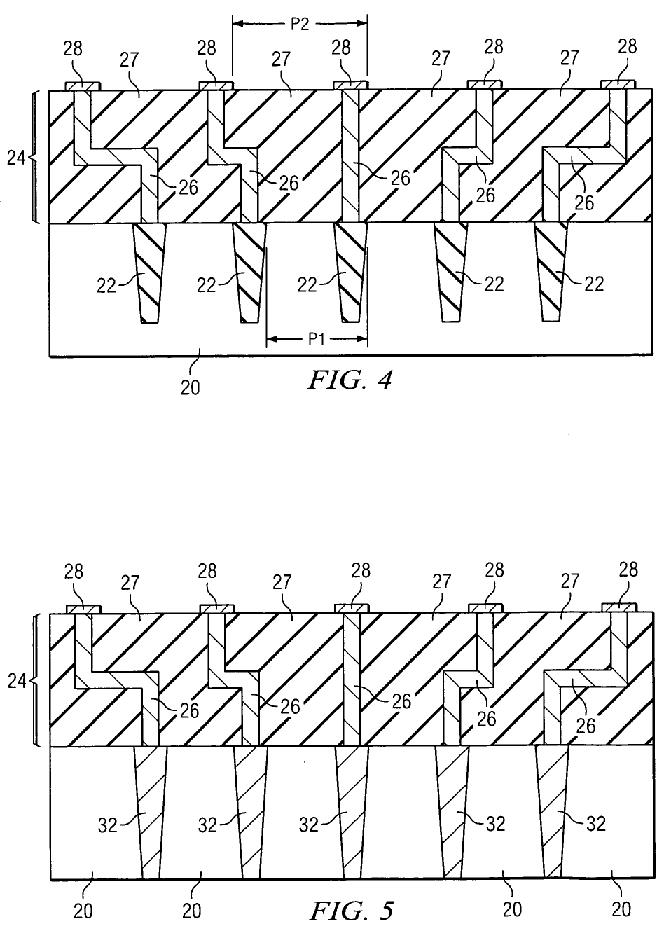

Referring to FIG. 4, an interconnect structure 24 is formed. Interconnect structure 24 includes one or more dielectric layers in which metal lines and vias are formed. The metal lines and vias are schematically illustrated as conductive features 26. Metallization layers are formed in dielectric layers 27 and dielectric layers 27 may have a high dielectric constant (k value), for example greater than about 3.9, or a low k value, depending on the testing requirement. Interconnect structure 24 routes the electrical connection from deep dielectric plugs 22 (which will be subsequently replaced with conductive materials) to contact pads 28, which are located on top of interconnect structure 24. The steps for forming interconnect structure 24 and contact pads 28 are well-known in the art, thus are not repeated herein. The pitches P2 of contact pads 28 are preferably greater than the pitches P1 of deep plugs 22. Bonding pads 28 preferably match the pitches and the distribution of the chip-probing system, for example, the probe pins of probe cards or contact pads of load boards. In an exemplary embodiment, pitches P2 are greater than about 60 μm, and more preferably between about 60 μm and about 200 μm.

In FIG. 5, the above-discussed structure is polished from the bottom side, and thus deep plugs 22 are exposed. Deep plugs 22 are then selectively removed from semiconductor substrate 20, preferably by etching. The openings left by the removal of deep plugs 22 are filled with conductive materials, which preferably include tungsten, aluminum, copper, titanium, tantalum, and combinations thereof. The resulting features in the openings are through-substrate vias 32, also sometimes referred to as through-silicon vias or through-wafer vias in the art. Apparently, through-substrate vias 32 have pitches P1, same as the pitches of deep plugs 22, wherein pitches P1 between through-substrate vias 32 are preferably less than about 60 μm. Pitches P2 of contact pads 28 are preferably greater than pitches P1. In practical cases, pitches P1 match the pitches of the bonding pads on the semiconductor chips to be tested. Therefore, pitches P1 may be of any value, and may even be less than about 20 μm.

Through-substrate vias 32 are vias that extend from the top surface of the substrate 20 to its back surface. It should be realized, however, that through-substrate vias 32 may be formed using other methods besides the illustrated example.

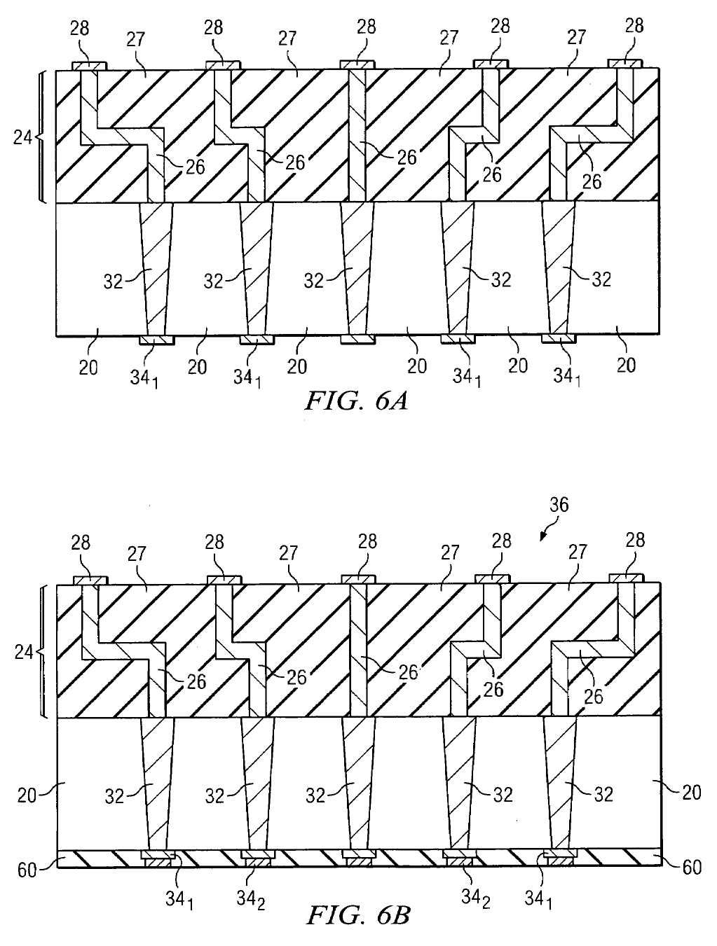

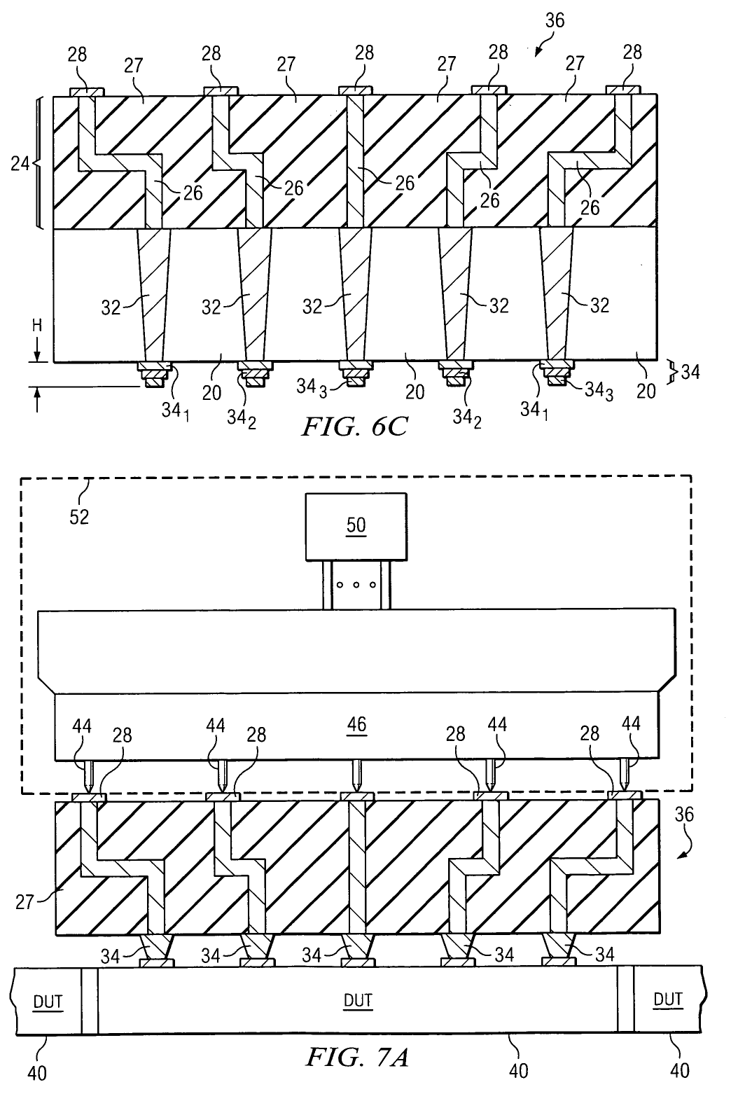

FIGS. 6A through 6C illustrate the formation of contact pads 34. In the preferred embodiment, contact pads 34 are formed as a stacked structure with the end portions being narrower than the base portions. Referring to FIG. 6A, first portions 34₁ of contact pads 34 are formed. Contact pad portions 34₁ and the subsequently formed portions are preferably formed of aluminum, copper, tungsten, titanium, tantalum, and combinations thereof. In a first embodiment, contact pad portions 34₁ are formed by depositing or plating a metal layer, then patterning the metal layer, thus leaving contact pad portions 34₁. In alternative embodiments, a silicon layer (or dielectric layer) is grown on the back surface of substrate 20. Openings are then formed in the silicon/dielectric layer. A metallic material is filled into the openings, followed by a chemical mechanical polish.

Referring to FIG. 6B, a silicon or dielectric layer 60 is grown/deposited on the back surface of substrate 20. Openings, which preferably have a smaller width than contact pad portions 34₁, are then formed in silicon/dielectric layer 60. A metallic material is filled into the openings, followed by a chemical mechanical polish. The remaining portions of the metallic material form contact pad portions 34₂.

The process illustrated in FIG. 6B may be repeated to form more contact portions, each having a decreased width over its base portions. After the final portions are formed, the grown or deposited silicon/dielectric layers, such as silicon/dielectric layer 60, are etched back, and thus contact pads 34 are left. The height H of contact pads 34 beyond the bottom surface of substrate 20 is preferably greater than about 3 μm. An advantageous feature of contact pads 34 is that they have a relatively flat contact surface, thus are less likely to damage the bonding pads of the semiconductor chips. The formation of interposer 36 is thus finished. Interposer 36 acts as a pitch converter for converting the pitches of semiconductor chips to be tested to the pitches of the load boards or the probe cards.

In the embodiment shown in FIGS. 6A through 6C, contact pads 34 have top portions that are narrower than the base portions. In an alternative embodiment, contact portions 34₁, 34₂ and 34₃ have substantially similar horizontal dimensions. Also, similar processes may be performed so that contact pads 34 have greater heights H.

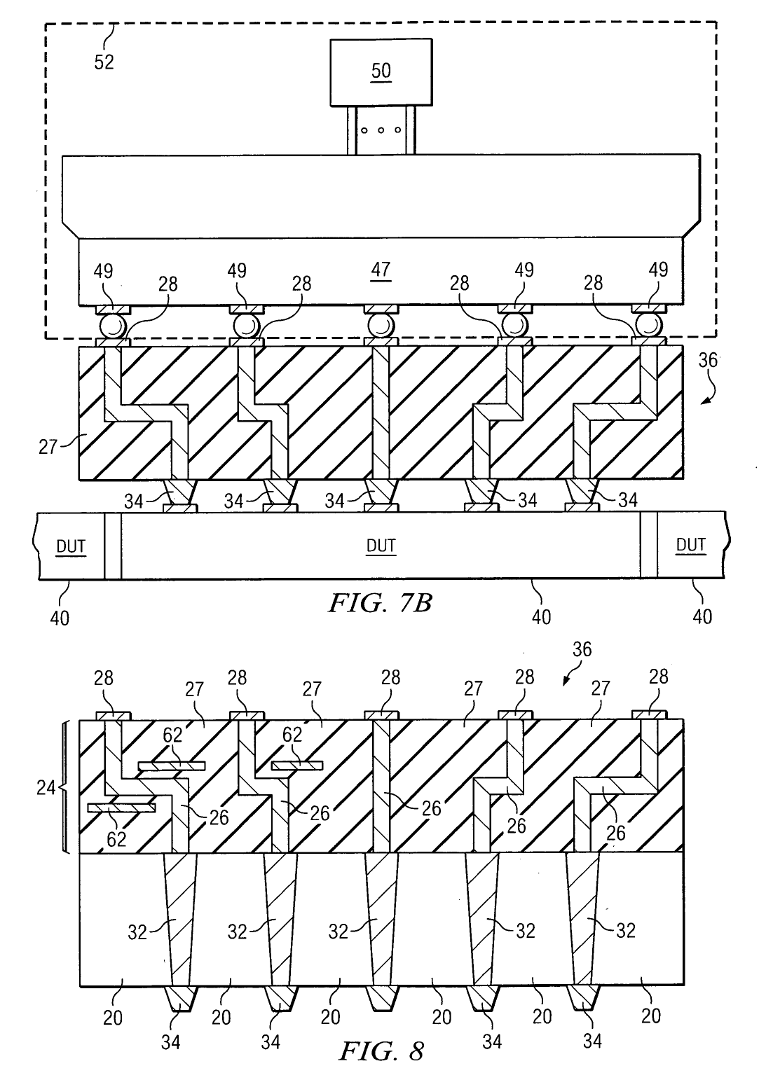

Exemplary connections of the interposer into the testing system are illustrated in FIGS. 7A and 7B. In a first exemplary embodiment, as is illustrated in FIG. 7A, chip-probing system 52 includes a probe card 46, which further includes probe pins 44. Probe pins 44 are put into contact with contact pads 28 of an interposer 36, wherein contact pads 28 are designed to match the pitches and the distribution of probe pins 44. Probe card 46 and interposer 36 are preferably physically integrated as one unit. The probe card can also be designed to have a built-in interposer. A wafer 40 containing a plurality of semiconductor chips is placed under interposer 36. Chip-probing system 52 and interposer 36 are aligned to one of the semiconductor chips, and contact pads 34 are put into contact with bonding pads on the semiconductor chips. The electrical connections to the semiconductor chips are routed to automated test equipment (ATE) 50, and the semiconductor chips are tested. After one semiconductor chip is tested, probe card 46 and interposer 36 are aligned to another semiconductor chip.

In a second exemplary embodiment, as is illustrated in FIG. 7B, chip-probing system 52 includes a load board 47, which further includes contact pads 49. Contact pads 49 are put into contact with contact pads 28, which are designed to match the pitches and the distribution of contact pads 49. Load board 47 and interposer 36 are preferably physically integrated as one unit, for example, through solder bumps.

An advantageous feature of the present invention is that interposer 36 is formed on a semiconductor substrate and the interconnect structure is formed using commonly used methods. Therefore, interposer 36 may be easily customized to suit different test requirements. FIG. 8 illustrates an interposer having built-in impedance matching lines/plates 62. As is known in the art, impedance matching is important in the design and testing of high frequency integrated circuits. Since the chip-probing systems are generic systems and cannot be customized according to each of the chips to be tested, serious impedance mismatching could occur, which significantly affects the operation of the high-frequency integrated circuits, hence the test results. Impedance matching devices, such as metal lines/plates 62, can easily be built into the interposer 36 by forming extra metal lines, which are disconnected from interconnect structure 24 of the interposer 36.

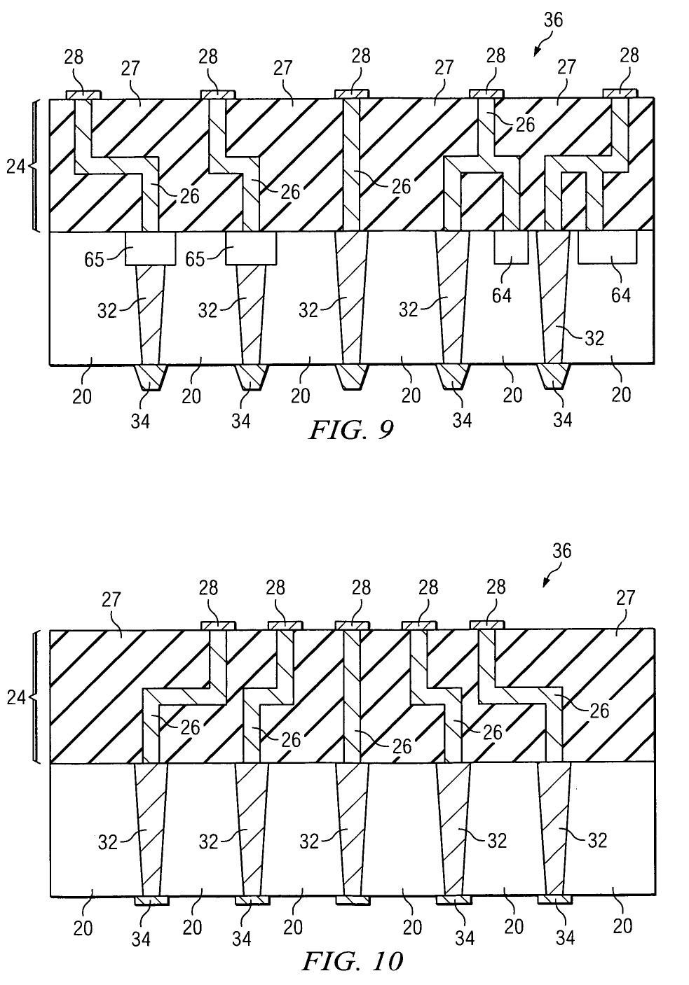

A further advantageous feature of the present invention is that active circuits 64 may be formed in interposer 36, as are illustrated in FIG. 9. Since some chips are not optimally designed for testing purposes, the chip-probing systems may not be suitable for testing certain integrated circuits. For example, connecting lines from semiconductor chips to the automated test equipment are typically significantly longer than metal lines in the semiconductor chips. Therefore, active circuits 65, such as buffers that are designed to drive integrated circuits and to improve switching speed, and/or amplifiers that are used to amplifying signals, may be built into interposer 36 and serially connected to interconnect structure 24. Active circuits 64, on the other hand, are connected in parallel to interconnect structure 24. Exemplary circuits 64 include electrostatic discharge circuits such as diodes. Substrate 20 is formed of semiconductor materials, thus active circuits 64 and 65 may be formed using conventional integrated circuit formation processes. The active circuits that can be built into interposer 36 and used for testing include buffers, level shifters, electrostatic discharge (ESD) structures, filters, A/D (D/A) converters, etc.

In the preferred embodiments, through-substrate vias 32 have smaller pitches than bonding pads over the semiconductor substrate. In alternative embodiments, as shown in FIG. 10, through-substrate vias 32 have greater pitches than the pitches of contact pads 28. Accordingly, contact pads 34 will be electrically connected to the chip-probing system side, which have greater pitches, while the contact pads 28 will be connected to the semiconductor chips.

The preferred embodiments of the present invention have several advantageous features. By connecting an interposer between the chip-probing system and semiconductor chips, the chip-probing system can be used to test semiconductor chips with significantly finer pitches. This solves the problem of the pitches of existing probe cards not being small enough for many semiconductor chips, which have increasingly smaller pitches. In addition, the cost for constantly replacing expensive probe cards is saved. Since interposers are formed using standard integrated formation processes, a plurality of interposers can be formed out of one wafer, thus the making and using of interposers is cost effective.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, and composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. An apparatus for testing integrated circuits comprising:
a substrate;
an interconnect structure over the substrate;
a first plurality of pads with a first pitch over the interconnect structure, wherein the first pitch is configured to match a pitch of a chip-probing system;
a second plurality of pads underlying the substrate, wherein the second plurality of pads have a second pitch matching a pitch of bonding pads on semiconductor chips, and wherein the second pitch are smaller than the first pitch; and
a plurality of through-substrate vias in the semiconductor substrate, wherein the first and the second plurality of pads are interconnected through the plurality of through-substrate vias.

2. The apparatus of claim 1, wherein the first pitch is greater than about 60 μm.

3. The apparatus of claim 1, wherein the first pitch is between about 60 μm and about 200 μm.

4. The apparatus of claim 1, wherein the second pitch is less than about 60 μm.

5. The apparatus of claim 1, wherein the second pitch is less than about 20 μm.

6. The apparatus of claim 1 further comprising an active circuit formed on the substrate, wherein the active circuit is electrically connected to the interconnect structure, and wherein the substrate is formed of a semiconductor material.

7. The apparatus of claim 6, wherein the active circuit is selected from the group consisting essentially of a buffer, an amplifier, an electrostatic discharge device, a level shifter, a filter, and combinations thereof.

8. The apparatus of claim 6 further comprising an impedance matching device in the substrate.

9. A chip-probing system comprising:
a probe head comprising probe pins/pads; and
an interposer comprising:
a substrate;
a first plurality of contact pads on a first side of the interposer and electrically connected to the probe pins/pads, wherein the first plurality of contact pads have a first pitch;
a second plurality of contact pads on a second side of the interposer opposite the first side, wherein the second plurality of contact pads have a second pitch less than the first pitch; and
through-substrate vias in the substrate and interconnecting the first and the second plurality of contact pads.

10. The chip-probing system of claim 9, wherein the first pitch is greater than about 60 μm, and wherein the second pitch is less about 60 μm.

11. The chip-probing system of claim 9, wherein the substrate is a semiconductor substrate.

12. The chip-probing system of claim 9, wherein the interposer further comprises an active circuit formed on the substrate, wherein the active circuit is electrically connected to the first and the second plurality of contact pads.

13. The chip-probing system of claim 12, wherein the active circuit is selected from the group consisting essentially of a buffer, an amplifier, an electrostatic discharge device, a level shifter, a filter, and combinations thereof.

14. The chip-probing system of claim 9, wherein the second pitch is less than about 20 μm.

15. A method of probing a semiconductor chip, the method comprising:
providing a semiconductor chip having a plurality of bonding pads thereon;
providing probing equipment; and
connecting an interposer between the semiconductor chip and the probing equipment, wherein the interposer comprises:
a first plurality of contact pads on a first side of the interposer and in physical contact with the probing equipment; and
a second plurality of contact pads on a second side of the interposer and connected to the bonding pads, wherein the first and the second plurality of contact pads are interconnected by through-substrate vias in a substrate of the interposer.

16. The method of claim 15, wherein a pitch of the first plurality of contact pads is greater than about 60 μm.

17. The method of claim 15, wherein a pitch of the first plurality of contact pads is between about 60 μm and about 200 μm.

18. The method of claim 15 further comprising forming a circuit selected from the group consisting essentially of an active circuit and an impedance-matching line in the interposer, wherein the impedance-matching line is electrically disconnected from the contact pads.

19. The method of claim 18, wherein the active circuit is selected from the group consisting essentially of a buffer, an amplifier, an electrostatic discharge device, a level shifter, a filter, and combinations thereof.

20. The method of claim 15, wherein the interposer comprises a semiconductor substrate.
